(19) United States
(12) Patent Application Publication
(10) Pub. No.: US 2025/0372531 A1
(43) Pub. Date: Dec. 4, 2025

(54) INJECTED NOISE CURRENT MINIMIZATION

(71) Applicant: VISTEON GLOBAL TECHNOLOGIES, INC., Van Buren Township, MI (US)

(72) Inventor: Alan J. Joseph, Shelby Township, MI (US)

(73) Assignee: VISTEON GLOBAL TECHNOLOGIES, INC., Van Buren Township, MI (US)

(21) Appl. No.: 19/223,523

(22) Filed: May 30, 2025

Related U.S. Application Data
(60) Provisional application No. 63/654,009, filed on May 30, 2024.

(51) Int. Cl. H01L 23/552; B60L 53/22; H01L 23/373; H01L 25/07; H10D 80/20

(52) U.S. Cl. CPC H01L 23/552; B60L 53/22; H01L 23/3735; H01L 25/072; H10D 80/251; B60L 2210/10

(57) ABSTRACT

A hybrid power phase leg includes a phase node, a heatsink, a first semiconductor switch, and a second semiconductor switch. The first semiconductor switch includes a first cooling side, a first power node that neighbors the first cooling side, and a first switching node. The first cooling side is thermally connected to the heatsink and the first switching node is electrically connected to the phase node. The first switching node pulls the phase node toward a positive voltage rail while in a conductive state. The second semiconductor switch includes a second cooling side, a second power node that neighbors the second cooling side, and a second switching node. The second cooling side is thermally connected to the heatsink and the second switching node is electrically connected to the phase node. The second switching node pulls the phase node toward a negative voltage rail while in the conductive state.

### CROSS-REFERENCE TO RELATED APPLICATIONS

This application claims the benefit of U.S. Provisional Application No. 63/654,009, filed May 30, 2024, which is hereby incorporated by reference in its entirety.

### TECHNICAL FIELD

The present disclosure generally relates to minimizing injected noise currents, such as with the use of a hybrid power phase leg configured for improving electromagnetic compatibility (EMC) performance by minimizing noise currents injected into a heatsink chassis potential and/or other componentry.

### BACKGROUND

A standard phase leg for power electronic circuits includes two semiconductor switches connected between a positive potential and a negative potential. A middle node of the phase leg may be switched between the positive potential and the negative potential, depending on which semiconductor switch is “on”. A cooling surface of each semiconductor switch is thermally connected to a heatsink through an electrically insulating and thermally conductive medium. Since the cooling surfaces and heatsink are electrically insulated from each other, but separated by a small distance, parasitic capacitors are established therebetween. Therefore, switching the middle node causes a voltage transition during the switching action, and therefore a current flows through at least one of the parasitic capacitors into the heatsink. The injected current results in undesirable electromagnetic interference (EMI) emissions.

Accordingly, those skilled in the art continue with research and development efforts in the field of injected noise current minimization.

### SUMMARY

A hybrid power phase leg is provided herein. The hybrid power phase leg includes a phase node, a heatsink, a first semiconductor switch, and a second semiconductor switch. The first semiconductor switch is of a first type. The first type includes a first cooling side, a first power node that neighbors the first cooling side, and a first switching node physically remote from the first cooling side. The first cooling side is thermally connected to and electrically isolated from the heatsink, the first power node is electrically connected to a positive voltage rail, and the first switching node is electrically connected to the phase node. The first switching node pulls the phase node toward the positive voltage rail while in a conductive state. The second semiconductor switch is of a second type. The second type includes a second cooling side, a second power node that neighbors the second cooling side, and a second switching node physically remote from the second cooling side. The second cooling side is thermally connected to and electrically isolated from the heatsink, the second power node is electrically connected to a negative voltage rail, and the second switching node is electrically connected to the phase node. The second switching node pulls the phase node toward the negative voltage rail while in the conductive state.

The above features and advantages and other features and advantages of the present teachings are readily apparent from the following detailed description of the best modes for carrying out the teachings when taken in connection with the accompanying drawings.

### BRIEF DESCRIPTION OF THE DRAWINGS

FIG. 1 illustrates a schematic diagram of a system in accordance with one or more exemplary embodiments.

FIG. 2 illustrates a schematic diagram of a hybrid power phase leg in accordance with one or more exemplary embodiments.

FIG. 3 illustrates a schematic cross-sectional diagram of the hybrid power phase leg in accordance with one or more exemplary embodiments.

The present disclosure may have various modifications and alternative forms, and some representative embodiments are shown by way of example in the drawings and will be described in detail herein. Novel aspects of this disclosure are not limited to the particular forms illustrated in the above-enumerated drawings. Rather, the disclosure is to cover modifications, equivalents, and combinations falling within the scope of the disclosure as encompassed by the appended claims.

### DETAILED DESCRIPTION

Embodiments of the disclosure generally provide for a hybrid power phase leg system and/or method. In various embodiments, the hybrid power phase leg system implements two semiconductor switches of two different types connected between a positive potential and a negative potential. A middle node of the phase leg may switch between the positive potential and the negative potential, depending on which semiconductor switch is conducting (e.g., “on”). If SiC or Si is used for one of the two semiconductor types, a cooling surface of the semiconductor switch is thermally tied to a drain node of a metal-oxide-silicon field-effect-transistor (MOSFET). If GaN is used for one of the two semiconductor types, the cooling surface is tied to a source node of a MOSFET. In some embodiments, a single semiconductor switch design (e.g., SiC, Si or GaN) may be utilized by essentially flipping the die inside the package of one of the devices in the hybrid phase leg. Accordingly, the semiconductor construction and/or material may vary, optionally, as long as the thermal pads are managed as noted. While currently described in terms of MOSFET semiconductor switches, the semiconductor switches may be various kinds of switching device such as an insulated-gate bipolar transistors (IGBT) and/or diodes. For the purposes of the disclosure, the drain node of a MOSFET is similar to a collector node of an IGBT or a cathode node of a diode. Likewise, the source node of a MOSFET is similar to an emitter node on an IGBT or an anode node of a diode. In various implementations, the switching node is used as one of the cooling surfaces of the two semiconductor devices.

An aspect of the present disclosure relates to using a SiC (or Si) semiconductor switch with a thermal pad having the electrical potential of a drain (in the instance of a MOSFET), and a GaN semiconductor switch with the thermal pad having the electrical potential of a source. Arranged as a phase leg with the SiC (or Si) semiconductor as the top device and the GaN semiconductor as the bottom device, neither cooling surface is electrically connected to the switching node (or phase node) between the two semiconductor switches. As such, during a switching transition of the phase leg, a minimal or zero noise current injected from the semiconductor to the heatsink through the thermal pads, which may in turn improve electromagnetic compatibility (EMC) performance through the minimization or elimination of a source of conducted emissions.

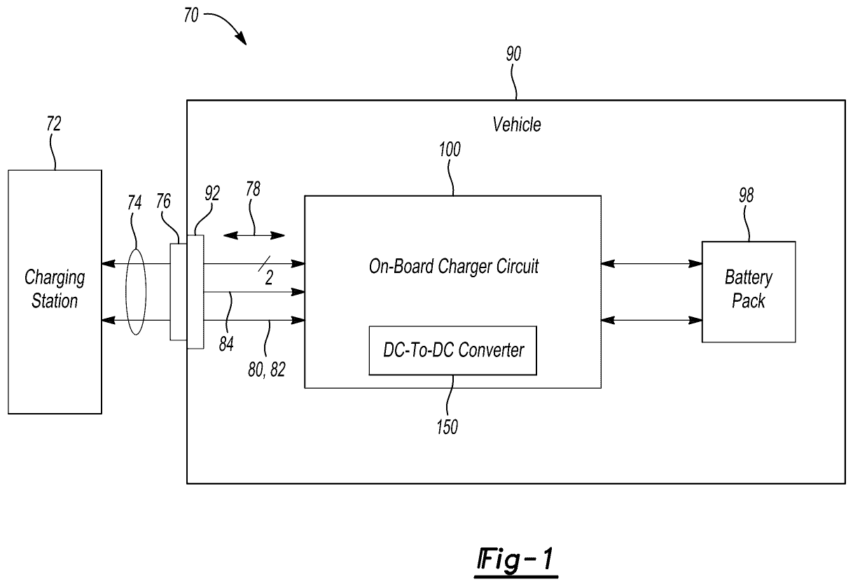

FIG. 1 illustrates a schematic diagram of a system 70 in accordance with one or more exemplary embodiments. The system 70 generally includes a charging station 72 and a vehicle 90. The charging station 72 includes a charging cable 74 and a charging plug 76. The vehicle 90 includes a charging socket 92, a battery pack 98, and an on-board charger circuit 100. The on-board charger circuit 100 includes a DC-to-DC converter 150.

Electrical power 78 may flow between the charging station 72 and the on-board charger circuit 100 in either direction via the charging cable 74, the charging plug 76 and the charging socket 92. The electrical power 78 may be single-phase alternating-current (AC) electrical power.

A control signal 80 may be presented from the charging plug 76, through the charging socket 92 to the on-board charger circuit 100. The control signal 80 may convey one of multiple commands 82 to on-board charger circuit 100. The commands 82 instruct the on-board charger circuit 100 a number of phases in the electrical power 78 and a direction that the electrical power 78 is flowing (e.g., into the on-board charger circuit 100 via the charging socket 92 or out of the charging socket 92 from the on-board charger circuit 100.

A communication signal 84 may be exchanged between the charging station 72 and the on-board charger circuit 100 via the charging cable 74, the charging plug 76, and the charging socket 92. The communication signal 84 may provide standard signaling information between the charging station 72 and the on-board charger circuit 100 to start, control, and stop the flow of the electrical power 78.

The charging station 72 is operational to provide electrical power (e.g., electrical current at a voltage) to the vehicle 90 to recharge onboard batteries of the vehicle 90. In various embodiments, the charging stations 72 may be compliant with the SAE International J1772 standard and/or the International Electrotechnical Commission (IEC) 61851-1 standard. The charging stations 72 may be a Level 1 AC or a Level 2 AC charger. Other charging standards may be implemented to meet the design criteria of a particular application. Some charging stations 72 may be placed at fixed locations. Other charging stations 72 may be mobile.

The charging plug 76 implements an electric charging handle. The charging socket 92 implements a vehicle charging receptacle. The charging plug 76 is connectable and disconnectable from the charging socket 92. The charging plug 76 and the charging socket 92 are operational to transfer the electrical power 78, control signal 80, and the communication signal 84 between the charging station 72 and the vehicle 90.

The vehicle 90 implements an electric-powered vehicle, a hybrid vehicle, or a plug-in hybrid vehicle. In various embodiments, the vehicle 90 may be compliant with the SAE International J1772 standard and/or the International Electrotechnical Commission (IEC) 61851-1 standard. The vehicles 90 may implement Level 1 AC and/or Level 2 AC charging capabilities. Other standards may be implemented to meet the design criteria of a particular application. In various embodiments, the vehicle 90 may include, but is not limited to, a passenger vehicle, a truck, an autonomous vehicle, a motorcycle, a boat, and/or an aircraft. In some embodiments, the vehicles 90 may be a stationary object such as a room, a booth and/or a structure. Other types of vehicles 90 may be implemented to meet the design criteria of a particular application.

The battery pack 98 implements as a high-voltage rechargeable energy storage system. The battery pack 98 is configured to store electrical energy. The battery pack 98 is generally operational to receive electrical power from the on-board charger circuit 100 and provide electrical power to the on-board charger circuit 100. The battery pack 98 may include multiple battery modules electrically connected in series and/or in parallel. In various embodiments, the battery pack 98 may provide approximately 200 to 1000 volts DC (direct current) electrical potential. Other battery voltages may be implemented to meet the design criteria of a particular application.

The on-board charger circuit 100 is coupled to the battery pack 98 and is operational to accept or alternately provide single-phase AC electrical power (e.g., electrical power 78). While operating in a single-phase input mode, the on-board charger circuit 100 is operational to convert an input single-phase electrical power to a first direct-current (DC) electrical power. The first DC electrical power may be filtered and subsequently converted to a second DC electrical power suitable for charging the battery pack 98. While operating in a single-phase output mode, the on-board charger circuit 100 may receive the second DC electrical power from the battery pack 98, convert the second DC electrical power to the first DC electrical power, and subsequently convert the first DC electrical power to an output single-phase AC electrical power. In various embodiments, the on-board charger circuit 100 may be located in the vehicle 90. In other embodiments, the on-board charger circuit 100 may reside at a fixed location.

The DC-to-DC converter 150 implements a unidirectional and/or a bidirectional converter of DC electrical power. Operations of the DC-to-DC converter 150 are governed by a controller within the on-board charger circuit 100. In a charging mode of operation, the DC-to-DC converter 150 converts first DC electrical power received from the charging station 72 to second DC electrical power. In a discharging mode of operation, the DC-to-DC converter 150 converts the second DC electrical power received from the battery pack 98 to the first DC electrical power. The second DC electrical power generally has a different (e.g., higher) voltage (e.g., 800 volts) than the first DC electrical power (e.g., 200 volts).

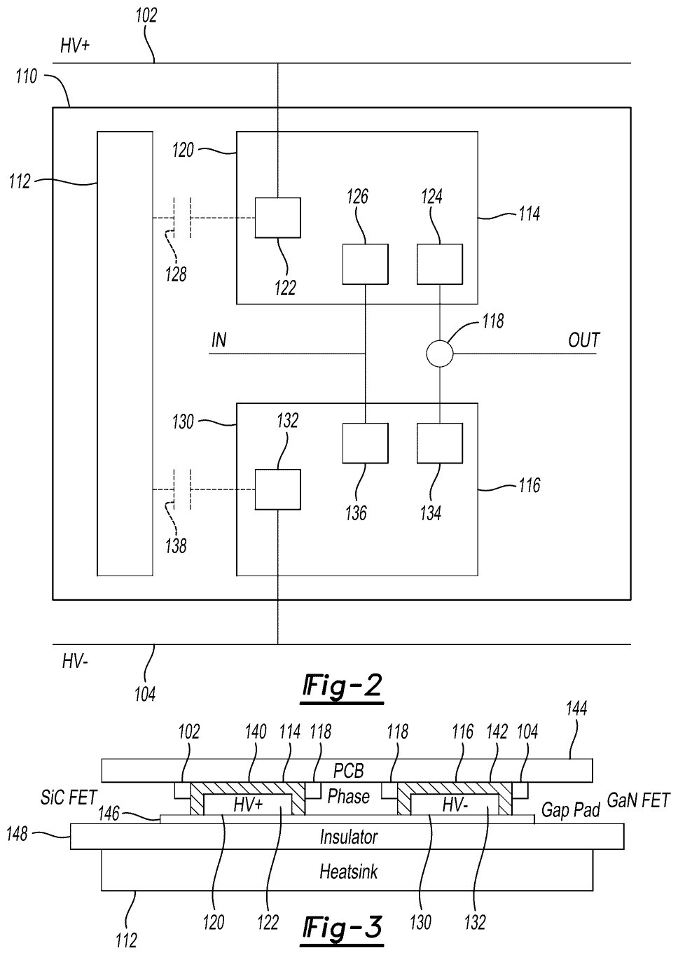

FIG. 2 illustrates a schematic diagram of a hybrid power phase leg in accordance with one or more exemplary embodiments. The hybrid power phase leg 110 may be connected between a positive voltage rail (or first power rail) 102 and a negative voltage rail (or second power rail) 104. In various embodiments, the positive voltage rail 102 may convey a high-voltage positive voltage (HV+) and the negative voltage rail 104 may convey a high-voltage negative voltage (HV−). An input signal (e.g., IN) may be received by the hybrid power phase leg 110. An output signal (e.g., OUT) is generated by the hybrid power phase leg 110.

The hybrid power phase leg 110 generally includes a heatsink 112, a first semiconductor switch (or device) 114, a second semiconductor switch (or device) 116, and a phase (or common) node 118. The input signal IN may be received by both the first semiconductor switch 114 and the second semiconductor switch 116. The output signal OUT may be generated at the phase node 118.

In various embodiments, the first semiconductor switch 114 may be a SiC or Si field effect transistor (FET). The first semiconductor switch 114 includes a first cooling side (or thermal pad) 120, a first power (drain) node 122, a first switching (source) node 124, and a first control (gate) node 126. A first parasitic capacitor 128 is formed between the heatsink 112 and the first power node 122. The first semiconductor switch 114 may be mounted to the heatsink 112 on the first cooling side 120.

The first power node 122 is directly connected to the positive voltage rail 102. The first power node 122 physically neighbors and is in thermal contact with the first cooling side 120. The first switching node 124 is electrically connected to the phase node 118. While the first semiconductor switch 114 is in a conducting state, the first switching node 124 pulls the phase node 118 towards the positive voltage rail 102. While the first semiconductor switch 114 is in a nonconducting state, the first switching node 124 may present a high impedance to the phase node 118.

The first control node 126 receives the input signal IN. The first semiconductor switch 114 is in the conducting state while the input signal IN is in an active voltage range and in the nonconducting state while the input signal IN is in an inactive voltage range.

In various embodiments, the second semiconductor switch 116 may be a GaN FET. The second semiconductor switch 116 includes a second cooling side (or thermal pad) 130, a second power (source) node 132, a second switching (drain) node 134, and a second control (gate) node 136. A second parasitic capacitor 138 is formed between the heatsink 112 and the second power node 132. The second semiconductor switch 116 may be mounted to the heatsink 112 on the second cooling side 130.

The second power node 132 is directly connected to the negative voltage rail 104. The second power node 132 physically neighbors and is in thermal contact with the second cooling side 130. The second switching node 134 is electrically connected to the phase node 118. While the second semiconductor switch 116 is in a conducting state, the second switching node 134 pulls the phase node 118 towards the negative voltage rail 104. While the second semiconductor switch 116 is in a nonconducting state, the second switching node 134 may present a high impedance to the phase node 118. The second control node 136 receives the input signal IN. The second semiconductor switch 116 is in the conducting state while the input signal IN is in an active voltage range and in the nonconducting state while the input signal IN is in an inactive voltage range.

Switching of the input signal IN causes the first semiconductor switch 114 and the second semiconductor switch 116 to change states. As a result, a major dynamic voltage swing (e.g., dV/dt) may be presented at the phase node 118. Because the first power node 122 is connected to the positive voltage rail 102, the second power node 132 is connected to the negative voltage rail 104, and the voltage rails 102-104 maintain basically steady state voltages, the switching of the input signal IN may result in minor dynamic voltage swings at the first power node 122 and the second power node 132. The minor dynamic voltage swings may present minor leakage currents through the first parasitic capacitor 128 and/or the second parasitic capacitor 138 to the heatsink 112.

FIG. 3 illustrates a schematic cross-sectional diagram of the hybrid power phase leg 110 in accordance with one or more exemplary embodiments. The hybrid power phase leg 110 includes the heatsink 112, the first semiconductor switch 114 in a first package 140, the second semiconductor switch 116 in a second package 142, a printed circuit board 144, a gap pad 146 and a thermally conductive insulator 148. The positive voltage rail 102 is disposed on the printed circuit board 144 and electrically connects to the first power node 122 of the first semiconductor switch 114. The negative voltage rail 104 is disposed on the printed circuit board 144 and electrically connects to the second power node 132 of the second semiconductor switch 116.

The first power node 122 is oriented neighboring the first cooling side 120 of the first semiconductor switch 114. The second power node 132 is oriented neighboring the second cooling side 130 of the second semiconductor switch 116. The first package 140 and the second package 142 are oriented with the first cooling side 120 and the second cooling side 130 facing the heatsink 112. The gap pad 146 and the thermally conductive insulator 148 are disposed between and thermally connect the first cooling side 120 and the second cooling side 130 to the heatsink 112.

In various embodiments, the thermally conductive insulator 148 is a Kapton® film. Kapton is a registered trademark of E. I. du Pont de Nemours and Company. The thermally conductive insulator 148 may have a thickness of 1 to 2 mils and have a 0.5 mil phase change. Other thermally conductive and electrically insulating materials may be used to meet the design criteria of a particular application.

The present disclosure may minimize and/or eliminate current injected into a heatsink though the thermal pads, such as with the phase legs using both a SiC (or Si) semiconductor and a GaN semiconductor. With the SiC (or Si) semiconductor connected to the positive voltage rail of the phase leg, the thermal pad may be electrically that same positive potential, and with the GaN semiconductor connected to the negative voltage rail of the phase leg, its thermal pad may be connected to that same negative potential. Thus, when the node between the two switches from the positive to the negative voltage rail, or from the negative to the positive voltage rail, the thermal pads of each semiconductor may not switch potentials. While the injected current into the heatsink, which is often chassis or earth connected, is not the sole source of EMI noise for the converter, it may be significant. An EMI filter in accordance with the present disclosure, if suitable, may be reduced in size and/or complexity, and optionally eliminated.

While one aspect of the present disclosure employs SiC (or Si) and GaN as the semiconductor switches, to use of just a SiC (or Si) or GaN may be achieved by essentially flipping the die inside the package of one of the devices in the phase leg. Accordingly, the semiconductor construction, material, etc. may vary, optionally as long as potential of the thermal pads is managed as noted.

Those having ordinary skill in the art will recognize that terms such as “above,” “below,” “front,” “back,” “upward,” “downward,” “top,” “bottom,” etc., may be used descriptively herein without representing limitations on the scope of the disclosure. Furthermore, the present teachings may be described in terms of functional and/or logical block components and/or various processing steps. Such block components may be comprised of various hardware components, software components executing on hardware, and/or firmware components executing on hardware.

The foregoing detailed description and the drawings are supportive and descriptive of the disclosure, but the scope of the disclosure is defined solely by the claims. As will be appreciated by those of ordinary skill in the art, various alternative designs and embodiments may exist for practicing the disclosure defined in the appended claims.

1. A hybrid power phase leg comprising:
a phase node;
a heatsink;
a first semiconductor switch of a first type, wherein:
the first type include a first cooling side, a first power node that neighbors the first cooling side, and a first switching node physically remote from the first cooling side; and
the first cooling side is thermally connected to and electrically isolated from the heatsink, the first power node is electrically connected to a positive voltage rail, and the first switching node is electrically connected to the phase node; and
the first switching node pulls the phase node toward the positive voltage rail while in a conductive state; and
a second semiconductor switch of a second type, wherein:
the second type includes a second cooling side, a second power node that neighbors the second cooling side, and a second switching node physically remote from the second cooling side; and
the second cooling side is thermally connected to and electrically isolated from the heatsink, the second power node is electrically connected to a negative voltage rail, and the second switching node is electrically connected to the phase node; and
the second switching node pulls the phase node toward the negative voltage rail while in the conductive state.

2. A method for injected noise current minimization comprising:
mounting a first semiconductor switch of a first type on a heatsink, wherein:
first type includes a first cooling side, a first power node that neighbors the first cooling side, and a first switching node physically remote from the first cooling side; and
the first cooling side is thermally connected to and electrically isolated from the heatsink, the first power node is electrically connected to a positive voltage rail, and the first switching node is electrically connected to a phase node;
mounting a second semiconductor switch of a second type on the heatsink; wherein:
the second type includes a second cooling side, a second power node that neighbors the second cooling side, and a second switching node physically remote from the second cooling side; and
the second cooling side is thermally connected to and electrically isolated from the heatsink, the second power node is electrically connected to a negative voltage rail, and the second switching node is electrically connected to the phase node;
pulling the phase node toward the positive voltage rail while the first semiconductor switch is in a conductive state; and
pulling the phase node toward the negative voltage rail while the second semiconductor switch is in the conductive state.

3. A vehicle comprising:
a battery pack; and
an on-board charger circuit coupled to the battery pack, wherein the on-board charger circuit includes:
a phase node;
a heatsink;
a first semiconductor switch of a first type, wherein:
the first type include a first cooling side, a first power node that neighbors the first cooling side, and a first switching node physically remote from the first cooling side; and
the first cooling side is thermally connected to and electrically isolated from the heatsink, the first power node is electrically connected to a positive voltage rail, and the first switching node is electrically connected to the phase node; and
the first switching node pulls the phase node toward the positive voltage rail while in a conductive state; and
a second semiconductor switch of a second type, wherein:
the second type includes a second cooling side, a second power node that neighbors the second cooling side, and a second switching node physically remote from the second cooling side; and
the second cooling side is thermally connected to and electrically isolated from the heatsink, the second power node is electrically connected to a negative voltage rail, and the second switching node is electrically connected to the phase node; and
the second switching node pulls the phase node toward the negative voltage rail while in the conductive state.

4. The hybrid power phase leg according to claim 1, wherein the first semiconductor switch includes a first control node that controls the conducting state and a nonconducting state of the first semiconductor switch in response to an input signal.

5. The hybrid power phase leg according to claim 4, wherein the second semiconductor switch includes a second control node connected to the first node of the firs semiconductor switch, and the second control node controls the conducting state and the nonconducting state of the second semiconductor switch in response to the input signal.

6. The hybrid power phase leg according to claim 1, wherein the first semiconductor switch is a first field effect transistor.

7. The hybrid power phase leg according to claim 6, wherein the first type is a Silicon carbide type of the first field effect transistor.

8. The hybrid power phase leg according to claim 7, wherein the second semiconductor switch is a second field effect transistor.

9. The hybrid power phase leg according to claim 8, wherein the second type is a Gallium nitride type of the second field effect transistor.

10. The hybrid power phase leg according to claim 1, further comprising a thermally conductive insulator mounted between the first cooling side and the heatsink.

11. The hybrid power phase leg according to claim 10, further comprising a gap pad mounted between the first cooling side and the thermally conductive insulator.

12. The method according to claim 2, further comprising:
controlling, through a first control node of the first semiconductor switch, the conducting state and a nonconducting state of the first semiconductor switch in response to an input signal.

13. The method according to claim 12, further comprising:
controlling, through a second control node of the second semiconductor switch, the conducting state and the nonconducting state of the second semiconductor switch in response to the input signal.

14. The method according to claim 2, wherein the first semiconductor switch is a first field effect transistor.

15. The method according to claim 14, wherein the first type is a Silicon carbide type of the first field effect transistor.

16. The method according to claim 15, wherein the second semiconductor switch is a second field effect transistor.

17. The method according to claim 16, wherein the second type is a Gallium nitride type of the second field effect transistor.

18. The method according to claim 1, further comprising:
mounting a thermally conductive insulator between both the first cooling side and the heatsink.

19. The method according to claim 18, further comprising:
mounting a gap pad between the first cooling side and the thermally conductive insulator.

20. The vehicle according to claim 3, wherein:
the first type of the first semiconductor switch is a Silicon type of field effect transistor, and
the second type of the second semiconductor switch is a Gallium nitride type of field effect transistor.
